(19) United States
(12) Patent Application Publication
(10) Pub. No.: US 2012/0295372 A1
(43) Pub. Date: Nov. 22, 2012

(54) METHOD OF MASKLESS MANUFACTURING OF OLED DEVICES

(75) Inventor: Holger Schwab, Aachen (DE)

(73) Assignee: KONINKLIJKE PHILIPS ELECTRONICS, N.V., EINDHOVEN (NL)

(21) Appl. No.: 13/519,401

(22) PCT Filed: Jan. 3, 2011
(86) PCT No.: PCT/IB2011/050003

§ 371 Date: Jun. 27, 2012

(30) Foreign Application Priority Data
Jan. 8, 2010 (EP) 10150323.9

(51) Int. Cl. H01L 51/56

(52) U.S. Cl. 438/22; 257/E51.019

(57) ABSTRACT

By the invention it is proposed a method of manufacturing of an OLED-device, comprising the steps of providing a carrier substrate, depositing a first electrode material layer on said carrier substrate, forming electrically separated areas within the deposited first electrode material layer, depositing a layer of an organic optoelectronic active material (105) on said first electrode material layer, depositing a second electrode material layer on said organic optoelectronic active material layer. The method is characterized in that in the steps of depositing the organic optoelectronic active material layer and the second electrode material layer the carrier substrate is covered maskless over its entire functional area with said layers and that at least the second electrode material layer is ablated or rendered non-conductive in at least selected areas to form non-conductive areas within the second electrode material layer.

### FIELD OF THE INVENTION

The invention relates to the field of manufacturing of OLED-devices (organic light emitting diode). In one aspect, the invention relates to a method maskless manufacturing OLED-devices in which method the structuring process of forming the OLED-devices is improved. In a further aspect, the invention relates to a light emitting device as well as a system comprising an OLED-device manufactured according to an aspect of the invention.

### BACKGROUND OF THE INVENTION

OLED-devices are known from the state of the art. In general, an OLED-device consists at least of a first electrode material arranged on a carrier substrate, an organic optoelectronic active material deposited on the first electrode material, and a second electrode material covering at least partially the organic optoelectronic active material. One of the electrode materials acts as cathode layer, while the other electrode material acts as anode layer. As optoelectronic active material electroluminescenting materials, such as light emitting polymers, like e.g. poly(p-phenylenevinylene) (PPV), or light emitting low molecular weight materials, like e.g. aluminum tris (8-hydroxyquinoline) can be used.

As carrier substrate insulating materials, like e.g. glass or plastic can be used. As electrode material compounds like e.g. transparent conductive oxides (TCO), like indium tin oxide (ITO), zinc oxide (ZnO), or metals, like e.g. copper, silver, gold, or aluminum can be used. It is also known from the state of the art to place a so called hole transporting layer between the electrode materials and the optoelectronic active material, like e.g. a PEDOT/PSS-layer (poly(3,4-ethylenedioxythiopene/polystyrolsulfonate) or a PANI/PSS-layer (polyaniline/polystyrolsulfonate), which lowering the injection barrier of the holes.

In operation, electricity is applied between the first electrode material layer and the second electrode material layer. The applied electricity causes an exited state of the optoelectronic active material by which relaxation to the non-exited state a photon is emitted. OLED-devices can be used, e.g. for displays or lighting.

It is known from the state of the art to manufacture OLED-devices by a process as described in the following.

As a first step, a substrate is manufactured in a patterning step. In this patterning step, a first electrode material is applied in pattern on a carrier substrate. The main function of this patterning step is to create electrically separated areas. This patterning can be done by e.g. depositing a functional layer by e.g. printing or sputtering through a shadow mask, etc.

In a subsequent step an OLED functional layer formed by an optoelectronic active material is applied. Small molecule functional layers are deposited by thermal evaporation in vacuum. The deposition of the organic material must be restricted in such a way that at least the cathode contacts are not coated. Usually, also the anode contacts are protected from the coating in order to achieve good electrical contacting later on. This structured deposition is achieved by means of a shadow mask. This mask is specific for each OLED design and is placed on top of the substrate during organic layer deposition. Masking can either be done in physical contact or with a small gap between the substrate and the mask. During the deposition process the shadow mask will be coated with the organic material.

In a next step a counter electrode is formed by deposition of a second electrode material layer. This is also applied in a vacuum thermal evaporation process. Also in this step the layer must be structured as otherwise a short circuit between the two electrode material layers, i.e. the cathode and the anode will occur. Also in this step the mask will be coated with material, wherein the cathode material typically is a metal like copper, silver, aluminum, gold, etc.

As the coated areas for the optoelectronic active material and cathode are different a different set of masks must be used in every of the mentioned process steps.

The quality of the OLED-device depends on the proper alignment of the different masks used as well as the thermal expansion of the mask and the substrate during deposition of the optoelectronic active material and the cathode layer. For example, the thermal expansion of a mask used in a manufacturing process according to the state of the art may be in the order of 0.5 mm for a typical temperature rise of 50° C. during the deposition of a cathode layer. Accordingly, the accuracy of the manufacturing process is limited to this thermal expansion. Therefore, the technique known from the state of the art has several drawbacks. As the masks are design specific a design change requires a new set of masks. This limits the throughput time for a design change and increases costs. The masks are coated during deposition. This requires regular cleaning and induces additional costs. Particles lost from the masks can lead to short circuits and reduce the yield of the production. The minimum feature size that can be realized is limited due to the thermal expansion of the masks, which scales with the substrate size, and the alignment accuracy. At least, the mask handling in vacuum is very expensive.

Another drawback of the masking methods known from the state of the art is that manufacturing of closed non electrode coated areas surrounded by coated electrode areas is not possible in one coating step due to the limitation in the required shadow mask. When using a mask, there will always be a ligament connecting the inner area of a closed non coated area to the outer coated area.

### SUMMARY OF THE INVENTION

It is an object of the invention to provide an improved method for the manufacturing of OLED-devices.

This object is achieved by a method manufacturing of an OLED-device, comprising the steps:
providing a carrier substrate;
depositing a first electrode material layer on said carrier substrate;
forming electrically separated areas within the deposited first electrode material layer;
depositing a layer of an organic optoelectronic active material on said first electrode material layer;
depositing a second electrode material layer on said organic optoelectronic active material layer, characterized in that in the steps of depositing the organic optoelectronic active material layer and the second electrode material layer the carrier substrate is covered maskless over its entire functional area with said layers and that at least the second electrode material layer is ablated or rendered non-conductive in at least selected areas to form non-conductive areas within the second electrode material layer.

Functional area in the meaning of the invention should be understood as the area of the carrier substrate surface on which the light emitting structure is formed. According to the invention, other areas of the carrier substrate surface, e.g. the rim area used for fixation of the OLED-device, can be left uncover, e.g. by restricting the deposition of electrode material and the optoelectronic active material to the functional area only or by masking the respective areas.

In one aspect of the invention it is the inventive idea to apply the different layers needed to built an OLED-device at the most over the whole area of the substrate and to subsequently ablate and/or to render non conductive specific layers in specific areas. This avoids the need of fine pattern aligning which improves the productivity of the OLED-production. Furthermore, ablating methods, like e.g. laser ablation or the like are more precise which allows forming of smaller pattern. A benefit of the inventive method is that the ablation step does not need to be performed in a vacuum chamber. This makes the overall production easier to handle and omits the need for large vacuum production chambers. Furthermore, due to the maskless deposition of the second electrode material also providing of closed non coated/non conductive electrode areas is possible.

According to an embodiment of the invention the second electrode material layer and the organic optoelectronic active material layer may be ablated to expose at least two contact pads on the two electrically separated areas of said first electrode material layer to form an anode and an cathode contact pad, wherein after the ablating one electrically separated area may substantially be free of the second electrode material layer and the organic optoelectronic active material layer while the other area may still substantially be covered with the second electrode material layer and the organic optoelectronic active material layer, and wherein the second electrode material layer remaining on one area may electrically be connected to the contact pad of the other area. It is a benefit of this embodiment that there is no need for a proper and time-consuming alignment of masks during the deposition of the organic optoelectronic active material layer and the second electrode material layer to left contact pad areas uncovered. This on one hand enables a higher productivity on the other hand allows smaller pattern sizes since there is no need to consider any thermal expansion of a mask. For example, when using a typical industrial laser system to ablate layers, the value for the alignment of the laser will be in the order of below 10 μm and the beam width will be in the order of 20 μm. This allows an accuracy of OLED-device which is about twenty-five times higher than using masking techniques.

According to an embodiment of the invention the second electrode material layer still remaining on one area may electrically be connected to the contact pad on the other area by applying an electrically conductive material of the group consisting of a silver metal paste, electrical conductive glue, and an electrochemically deposited metal. It should be understood that electrochemical deposition of a metal may be performed by any appropriate galvanic or autocatalytic deposition. It is a benefit of this embodiment that applying of these conductive materials is possible with a proper accuracy also at a high throughput, e.g. by using ink jet printing techniques or the like. When using an electrochemically deposited metal, an insulating material at least partially can be applied. This enables to avoid short circuits caused by unintended deposition of metal. The insulating material may also be applied by means of ink jet printing techniques. Alternatively, the electrical connection can be realized by wiring or applying an appropriate electrical conductive cover lid.

According to an embodiment of the invention the electrically conductive material connecting the second electrode material layer on one area to the contact pad of the other area may be annealed after being applied. Such annealing may be performed by a thermal annealing step, UV-induced annealing or any other appropriate annealing method. Thermal annealing may be performed by local application of heat, e.g. by means of a laser beam, micro-wave beam, UV-beam, IR-beam or the like, or by applying heat to the whole structure. Here, local application of heat may be preferred due the benefit that only small thermal expansion of the OLED-device will occur which will keep the mechanical stress low. To improve the annealing process step further, the electrical conductive material may comprise a compound which absorbs the irradiated electromagnetic radiation (i.e. light, micro-wave, UV, IR) and initiates and/or accelerates the annealing process. Such a compound may be a pigment, a radical starter, or the like. This may further improve the overall method by a time advantage due to an accelerated and improved annealing.

According to an embodiment of the invention prior to applying the electrically conductive material an insulating material may at least partially be applied. This has the benefit that electrical short circuits caused by the unintended deposition of electrical conductive material can be avoided.

In a variation of the method, the organic optoelectronic active material may be applied by a printing process, e.g. by use of printing solution process able functional materials.

According to an embodiment of the invention the electrical conductive material connecting the second electrode material layer on one area to the contact pad of the other area may be dimensioned to melt at a specific voltage and/or current density. This has the benefit that the electrical connection between the second electrode material layer on one area and the contact pad of the other area may act as an electrical fuse. This may avoid decomposition of the organic optoelectronic active material caused by overvoltage and the risk of burning.

The method according to the invention is applicable in the production process of different kinds of OLED-devices, like e.g. inverted OLED-devices in which the top electrode is the anode, or top emitting or transparent OLED-devices in which the top electrode and/or the bottom electrode are transparent. For the latter, a TCO may be used as electrode material. According to an embodiment of the invention the OLED-device may be an inverted OLED wherein the second electrode material layer will form the anode of the device, or it may be a top emitting OLED wherein the second electrode material layer may be a transparent layer, like e.g. a TCO. However, according to an embodiment of the invention at least one of the electrode material layers may be a TCO.

According to another embodiment of the invention the at least one of the electrode material layers may comprise a light scattering component or light scattering particles. This has the benefit that the light out-coupling may be increased which will increase the efficiency of the OLED-device.

According to an embodiment of the invention the electrically separated areas are formed by patterned deposition of the first electrode material layer. Such patterned deposition may be performed by commonly know masking of the substrate. Since the first electrode material layer is directly deposited on the substrate surface no alignment to prior deposited structures is necessary. Alternatively, the first electrode material layer may be deposited over wide areas of the substrate and patterning is performed by means of ablating methods, e.g. laser ablating, plasma etching, mechanical ablating, chemical ablating, etc. This may further increase the productivity of the overall production process in the manufacturing of OLED-devices.

According to an embodiment of the invention the second electrode material layer and/or the organic optoelectronic active material layer are ablated and/or rendered non-conductive at least partially by means of a laser-beam and/or plasma etching. The use of a laser-beam and/or plasma etching has the benefit that a very precise ablating is possible which enables to form very small structures with high accuracy. This may enable to reduce the size of a single OLED-device and to provide light emitting systems having an increased pixel density and/or resolution.

In a further variation of the method, the ablation is done from the substrate side.

According to another embodiment of the invention only the outline of an area of the second electrode material layer and/or the organic optoelectronic active material layer to be ablated is ablated by means of a laser-beam and/or plasma etching while the main area to be ablated is ablated by a mechanical and/or chemical ablation means. This has the benefit that the thermal energy introduced can be redused which may reduce the mechanical stress to the OLED-device caused by thermal expansion. An appropriate mechanical ablating methods may be the use of a sticky tape ablating the inner area of the outlined structure.

In an embodiment of the invention, a laser system is used for the ablation as well as the annealing. In such an embodiment, the laser system may comprise different laser sources and/or a laser source having an adjustable output and/or wavelength. This has the benefit that the production process can be performed on a single production system.

One of the advantages of the proposed method beside cost savings is the possibility to create small feature sizes as only the printing accuracy and/or the ablating accuracy limits the minimum size and/or spacing of the OLED-devices. In addition, all arrangements of OLED arrays can be realized with almost no limitation to the shape of the OLED.

In a further aspect, the invention relates to light emitting device, comprising an OLED-device manufactured according to any of the above disclosed embodiments of the inventive method. Such a light emitting device may have an increased pixel density and/or resolution due to the improved accuracy of the OLED-device.

In a further aspect, the invention relates to a system comprising an OLED-device manufactured according to any of the above disclosed embodiments of the inventive method and/or a light emitting device as disclosed above, the system being used in one or more of the following applications:
Office lighting systems
household application systems
shop lighting systems,
home lighting systems,
accent lighting systems,
spot lighting systems,
theater lighting systems,
fiber-optics application systems,
projection systems,
self-lit display systems,
pixelated display systems,
segmented display systems,
warning sign systems,
medical lighting application systems,
indicator sign systems, and
decorative lighting systems
portable systems
automotive applications
green house lighting systems

### BRIEF DESCRIPTION OF THE DRAWINGS

Additional details, features, characteristics and advantages of the object of the invention are disclosed in the sub claims, the figures and the following description of the respective figures and examples, which—in an exemplary fashion—show several embodiments and examples of materials according to the invention.

In the drawings:

FIG. 1 shows a process scheme for the production of OLEDs according to the state of the art;

FIG. 2 shows a process scheme according to an aspect of the invention;

FIG. 3 depicts the contacting of the second electrode material layer according to an aspect of the invention;

FIG. 4 shows the formation of pattern on an electrode material layer surface according to an aspect of the invention.

### DETAILED DESCRIPTION OF EMBODIMENTS

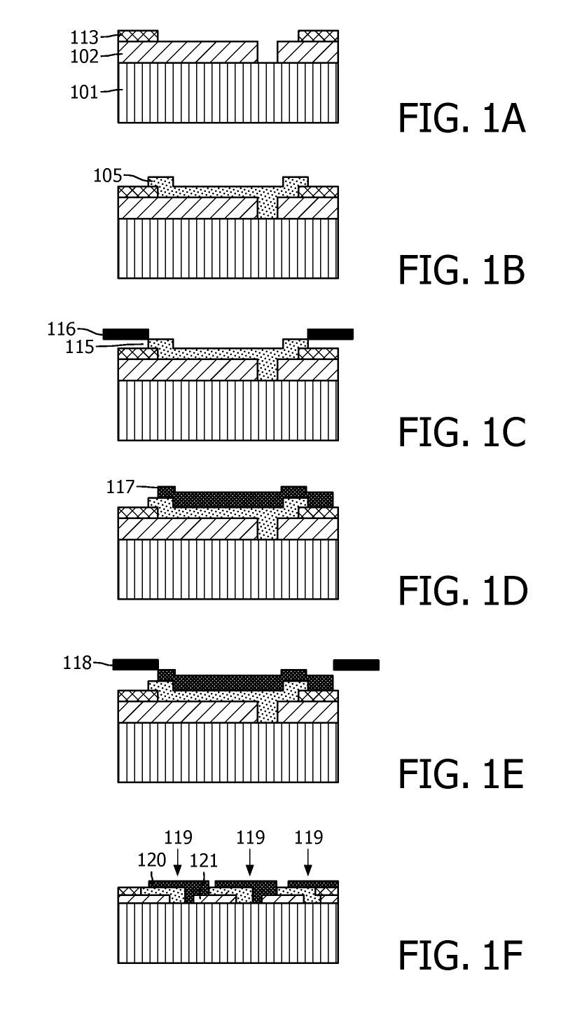

In FIG. 1, a scheme of a process for the production of OLEDs according to the state of the art is shown. In step 1 A, on a carrier substrate 101 a transparent conductor layer 102 is deposited in specific pattern defining the later OLED-device structure. The patterning can be done by masking the areas not to be covered by the deposit, like e.g. by sputtering through a shadow mask or printing methods. The transparent conductor may be ZnO, an ITO, and/or a PEDOT/PSS-layer. On this transparent conductor layer 102 optional metal lines 113 are deposited. The pattern structure is filled in step 1 B with an optoelectronic active material 105.

Small molecule optoelectronic active materials commonly are deposited by thermal evaporation in vacuum. The deposition of the organic material must be restricted in such a way that at least the cathode contacts 115 are not coated. Usually, also the anode contacts are protected from the coating in order to achieve good electrical contacting later on. As visible in step 1 C, this structured deposition is achieved by means of shadow masks 116. These masks 6 are specific for each OLED design and are placed on top of the substrate during organic optoelectronic active material deposition. In step 1 D, a cathode layer 117 is deposited. This also happens in a vacuum thermal evaporation process. The layer 117 must be structured, too, as otherwise a short circuit between the cathode layer 117 and the anode layer 102 will occur. Therefore, in cathode deposition a shadow mask 118 is used to protect areas in the device from deposition as depict in step 1 E. Also here, the mask 118 will be coated with material, wherein the cathode material typically is a metal like copper, silver, aluminum, gold, etc. As can be seen in step 1 F, when a serial connection of individual OLED segments 119 needs to be realized, a very complicated set of shadow masks is required as the anode 120 of one pixel needs to be connected with the cathode 121 of the next pixel.

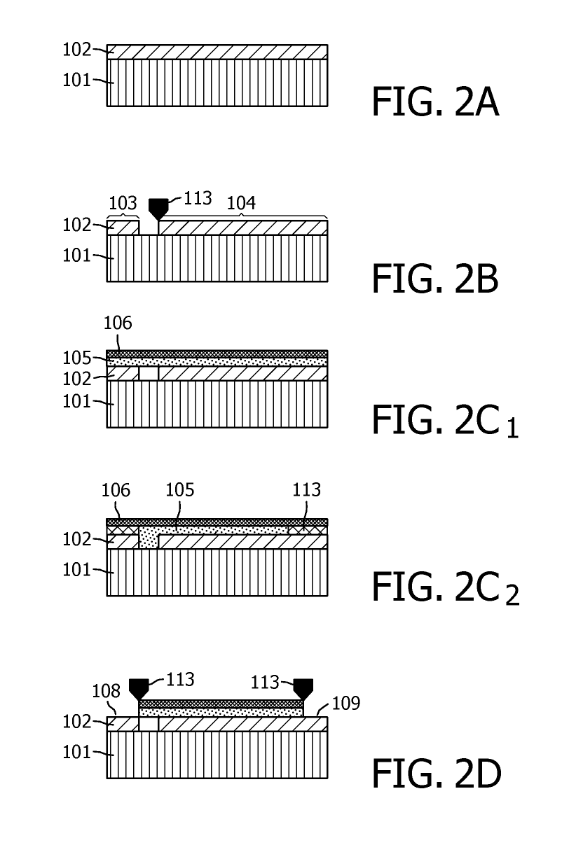

In FIG. 2, a process scheme according to an aspect of the invention is shown. In step 2 A, on a carrier substrate 101 a first electrode material layer 102 is deposited. The deposition may be applied as patterned depositions, e.g. by using commonly known masking techniques. Preferably, the first electrode material layer 102 is deposited essentially over the whole functional area of the substrate 101 and patterning is applied by ablating specific areas of the deposited first electrode material layer 102, e.g. by means of a laser-beam 113 or plasma etching. However, separated areas 103, 104 are formed by the patterning of the layer 102. On the patterned first electrode material layer 102 an organic optoelectronic active material layer 105 and a second electrode material layer 106 is deposited, as shown in step C₁. The organic optoelectronic active material may also fill pattern area between the separated areas 103 and 104, as shown in step C₂. In step D the second electrode material layer 106 and the organic optoelectronic active material layer 105 are ablated, e.g. by a laser-beam 113, to expose contact pads 108 and 109. Here, ablation is performed in the way that the electrically separated area 103 of the first electrode material layer 102 is substantially free of the second electrode material layer 106 and the organic optoelectronic active material layer 105, while the other electrically separated area 104 of layer 102 is still substantially covered with the layers of the second electrode material and the organic optoelectronic active material. It should be understood that the first and the second electrode material layers 102 and 106 may act as cathode or anode, respectively, dependent on the kind of the OLED-device in pattern. In a regular OLED-device, the second electrode material layer 106 may act as cathode and the first electrode material layer 102 may act as anode, while in an inverted OLED-device, the functionality of the electrode material layers may be reversed.

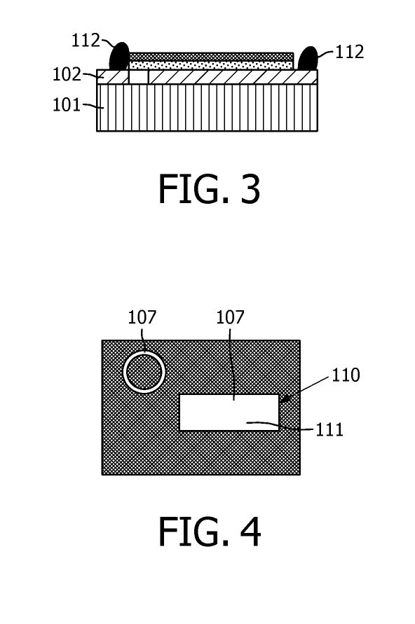

In FIG. 3 it is depicted how to electrically connect the second electrode material layer 106 to a respective contact pad 108. According to an aspect of the invention the electrical connection of the second electrode material layer is performed by means of an electrically conductive material 112. The material 112 may be a material of the group consisting of a silver metal paste, electrically conductive glue, and an electrochemically deposited metal. In a preferred embodiment, the material 112 is applied by means of ink jet printing. After applying the material 112 may be annealed according to an embodiment of the invention. Annealing may be performed by local heat exposure, e.g. by means of a laser-beam or focused micro-wave beam. Beneath connecting the second electrode material layer 106 to the contact pad 108, the electrically conductive material 112 may also be applied to the other contact pad 109 to increase the conductivity of this contact pad 109 for the electrical connection of the first electrode material layer 102 to an electric circuit. However, this has to be done very carefully to avoid the formation of short circuits between the first and the second electrode material layers 102 and 106.

FIG. 4 shows the formation of closed non-electrode material covered and/or non-conductive pattern on the second electrode material layer 106. By the inventive method such pattern can be formed without any ligaments by ablation of the deposited electrode layer in specific areas 107. According to an embodiment of the invention, only the outline 110 of a pattern is ablated by means of e.g. a laser-beam or plasma etching, while the inner area 111 of the pattern is ablated by mechanical means, e.g. a sticky tape. This has the benefit that the amount of heat introduced into the OLED-device is further reduced and thermal expansion is minimized.

The particular combinations of elements and features in the above detailed embodiments are exemplary only; the interchanging and substitution of these teachings with other teachings in this and the patents/applications incorporated by reference are also expressly contemplated. As those skilled in the art will recognize, variations, modifications, and other implementations of what is described herein can occur to those of ordinary skill in the art without departing from the spirit and the scope of the invention as claimed. Accordingly, the foregoing description is by way of example only and is not intended as limiting. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage. The invention's scope is defined in the following claims and the equivalents thereto. Furthermore, reference signs used in the description and claims do not limit the scope of the invention as claimed.

1. A method of manufacturing of an OLED-device, comprising the steps:
providing a carrier substrate;
depositing a first electrode material layer on said carrier substrate;
forming electrically separated areas within the deposited first electrode material layer;
depositing a layer of an organic optoelectronic active material on said first electrode material layer;
depositing a second electrode material layer on said organic optoelectronic active material layer, characterized in that in the steps of depositing the organic optoelectronic active material layer and the second electrode material layer the carrier substrate is covered maskless over its entire functional area with said layers and that at least the second electrode material layer is ablated or rendered non-conductive in at least selected areas to form non-conductive areas within the second electrode material layer.

2. The method according to claim 1, wherein the second electrode material layer and the organic optoelectronic active material layer are ablated to expose at least two contact pads on the two electrically separated areas of said first electrode material layer to form an anode and an cathode contact pad, wherein after the ablating one electrically separated area is substantially free of the second electrode material layer and the organic optoelectronic active material layer while the other area is still at least partially covered with the second electrode material layer and the organic optoelectronic active material layer, and wherein the second electrode material layer remaining on one area is electrically connected to the contact pad of the other area.

3. The method according to claim 2, wherein the second electrode material layer on the area is electrically connected to the contact pad by applying an electrically conductive material of the group consisting of a silver metal paste, a electrically conductive glue, and an electrochemically deposited metal.

4. The method according to claim 2, wherein the electrically conductive material connecting the second electrode material layer on one area to the contact pad of the other area is annealed after being applied.

5. The method according to claim 2, wherein at least one electrode material is a transparent conductive oxide.

6. The method according to claim 2, wherein prior to applying the electrically conductive material an insulating material is at least partially applied.

7. The method according to claim 2, wherein the electrically separated areas are formed by patterned deposition of the first electrode material layer.

8. The method according to claim 2, wherein the second electrode material layer and/or the organic optoelectronic active material layer are ablated and/or rendered non-conductive at least partially by means of a laser-beam and/or plasma etching.

9. The method according to claim 8, wherein only the outline of an area of the second electrode material layer and/or the organic optoelectronic active material layer to be ablated is ablated by means of a laser-beam and/or plasma etching while the main area to be ablated is ablated by a mechanical and/or chemical ablation means.

10. The method according to claim 9, wherein the main area is ablated by a sticky tape.

11. The method according to claim 9, wherein the electrical conductive material connecting the second electrode material layer on one area to the contact pad of the other area are dimensioned to melt at an applied voltage and/or current density causing an overvoltage of the OLED-device.

12-13. (canceled)
